(19) United States
(12) Patent Application Publication
(10) Pub. No.: US 2025/0183006 A1
(43) Pub. Date: Jun. 5, 2025

(54) MATCH NETWORK WITH VARIABLE CAPACITANCE AND SWITCHABLE ARRAY OF SOLID-STATE CAPACITANCE

(71) Applicant: Advanced Energy Industries, Inc., Denver, CO (US)

(72) Inventors: Denis Shaw, Fort Collins, CO (US); Courtney Crandell, Fort Collins, CO (US); Masahiro Watanabe, Windsor, CO (US)

(21) Appl. No.: 18/524,437

(22) Filed: Nov. 30, 2023

(51) Int. Cl. H01J 37/32; H03H 7/38

(52) U.S. Cl. CPC H01J 37/32183; H01J 37/32146; H03H 7/38; H01J 2237/327

(57) ABSTRACT

A match network with variable capacitance and a switchable array of solid-state capacitance. In one embodiment, a match network includes a variable capacitance and one or more solid-state capacitances switchably in parallel with the variable capacitance. The match network also includes a controller configured to control the variable capacitance to impedance match to a first impedance state of a plasma load, and to switch at least one solid-state capacitance into or out of parallel arrangement with the variable capacitance to impedance match to a second state of the plasma load.

### BACKGROUND

### Field

The present disclosure relates generally to plasma processing systems, and more specifically, to impedance matching in plasma processing systems.

### Background

In plasma processing, a match network helps provide an efficient pathway for power transfer between a generator and the plasma load. Modern plasma processing systems increasingly use multi-pulsed power for more advanced plasma control. However, multi-pulsing creates multiple impedance states, and conventional match network approaches are insufficient for impedance matching to the additional impedance states. Additionally, conventional match networks that use a variable capacitor often adjust the variable capacitor on a continuous or frequent basis to compensate for small variations in load impedance. These adjustments may wear the leadscrew of the variable capacitor over time and reduce the lifetime of the capacitor.

### SUMMARY

According to an aspect, a match network includes a variable capacitance and one or more solid-state capacitances switchably in parallel with the variable capacitance. The match network also includes a controller configured to control the variable capacitance to impedance match to a first impedance state of a plasma load, and to switch at least one solid-state capacitance into or out of parallel arrangement with the variable capacitance to impedance match to a second state of the plasma load.

According to another aspect, a method is disclosed where the method includes controlling a variable capacitance for impedance matching to a first impedance state of a plasma load, and switching one or more solid-state capacitances into or out of parallel arrangement with the variable capacitance for impedance matching to a second impedance state of the plasma load.

According to yet another aspect, a non-transitory processor-readable medium is disclosed that comprises instructions for execution by a processor or for configuring a field programmable gate array, the instructions comprising instructions to: control a variable capacitance for impedance matching to a first impedance state of a plasma load; and switch one or more solid-state capacitances into or out of parallel arrangement with the variable capacitance for impedance matching to a second impedance state of the plasma load.

### BRIEF DESCRIPTION OF THE DRAWINGS

FIG. 1 is a block diagram of a plasma processing system in accordance with an embodiment of this disclosure.

FIG. 2 is a graph depicting multi-pulsing in an example embodiment.

FIG. 3 shows a variable reactance section that is an example of the variable reactance section of FIG. 1.

FIG. 4 shows a variable reactance section that is another example of the variable reactance section of FIG. 1.

FIG. 5 is a flowchart illustrating a method of impedance tuning in an example embodiment.

FIG. 6 is a graph depicting an example of using a variable capacitance and solid-state capacitance in combination for impedance matching to load fluctuation.

FIG. 7 is a block diagram depicting physical components that may be used to implement an element controller in accordance with an embodiment of this disclosure.

### DETAILED DESCRIPTION

The following modes, features or aspects, given by way of example only, are described in order to provide a more precise understanding of the subject matter of several embodiments.

The word “exemplary” is used herein to mean “serving as an example, instance, or illustration.” Any embodiment described herein as “exemplary” is not necessarily to be construed as preferred or advantageous over other embodiments.

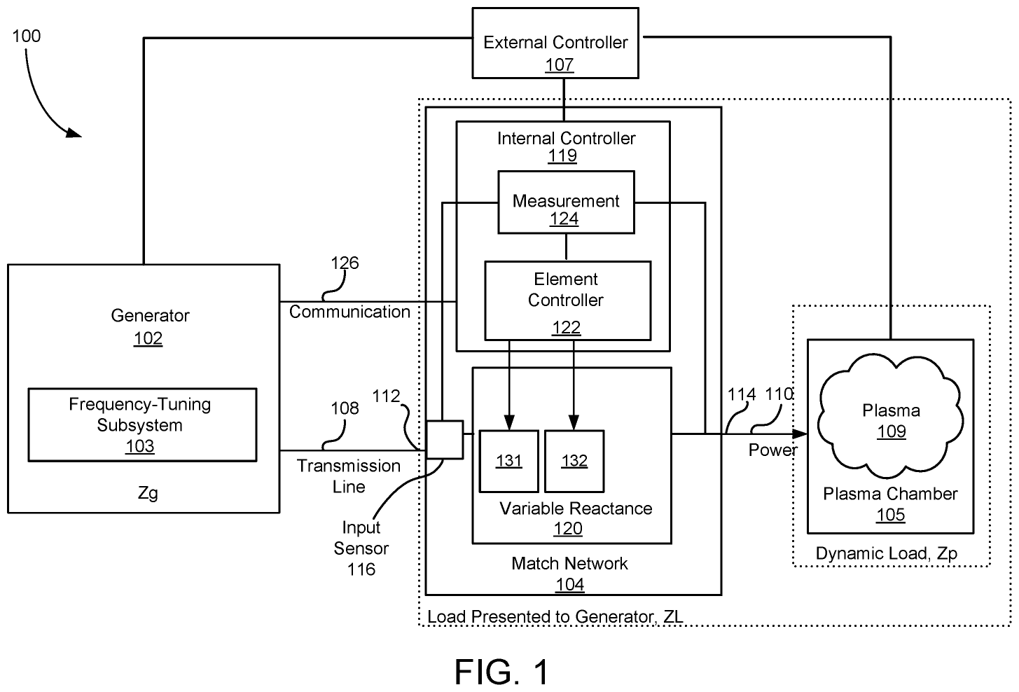

FIG. 1 is a block diagram of a plasma processing system 100 in accordance with an embodiment of this disclosure. The plasma processing system 100 includes a generator 102, match network 104, a plasma chamber 105, and an external controller 107. In operation, the generator 102 applies power (e.g., medium frequency power, radio frequency (RF) power, or power at any frequency where impedance matching is beneficial) to the match network 104 via a transmission line 108 (e.g., coaxial cable) and then onto the plasma chamber 105 via an electrical connection 110. In one embodiment, the generator 102 includes a frequency-tuning subsystem 103 that is configured to adjust a frequency of the generator 102.

The match network 104 includes an input 112 including an electrical connector (not shown) to couple to the generator 102 via the transmission line 108 and an output 114 including an electrical connector (not shown) to couple to the plasma chamber 105 via the electrical connection 110. The match network 104 also includes an input sensor 116 coupled to an internal controller 119, which includes a measurement section 124, an element controller 122, and a variable reactance section 120. Moreover, as described in greater detail below, the variable reactance section 120 includes a variable capacitance 131 and an array of one or more solid-state capacitances 132 switchably in parallel with the variable capacitance 131.

In general, the match network 104 operates to achieve a complex conjugate match between the generator 102 and the plasma load. That is, the internal controller 119 controls the variable reactance section 120 such that the impedance presented to the generator 102 (i.e., presented to the transmission line 108 at an input 112 of the match network 104) is a complex conjugate of the impedance of the dynamic load, Zp. In doing so, the measurement section 124 may monitor the impedance of the plasma 109, and the element controller 122 uses this measurement feedback to generate control signals to tune the capacitances accordingly. The internal controller 119 thus continuously adapts the match network 104 such that impedance matching may occur under changing plasma conditions. This impedance matching helps achieve efficient power transfer, stable plasma conditions, and controlled processing outcomes.

The plasma processing system 100 is generally configured to use multi-pulsing as a technique to finely control the plasma environment. Multi-pulsing involves applying a sequence of pulses having different parameters, such as different power levels, frequencies, duration, or timing between pulses. Compared to continuous wave or single-pulse approaches, multi-pulsing enables increased dynamic control of the plasma environment by tailoring the pulse sequence and parameters to the process being performed, material properties, and desired effects.

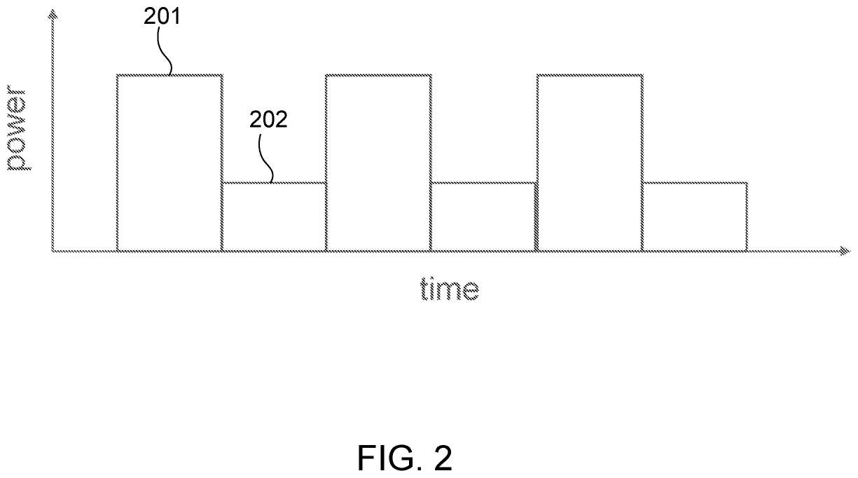

FIG. 2 is a graph depicting multi-pulsing in an example embodiment. In this example, the generator 102 applies dual-level pulsing to the plasma chamber 105 including a first power level 201 (e.g., high power state) and a second power level 202 (e.g., low power state) which alternate with one another in a repeating cycle over time. As mentioned, alternating between two or more states in this manner may produce several plasma processing benefits including increased control of plasma interaction with material. However, the use of two or more pulse states in plasma processing can make it difficult to achieve impedance matching. That is, as compared to single-pulse applications, multi-pulsing introduces an increased number of states for which impedance matching is to be performed.

Current approaches for match tuning dual-level pulsing typically involve using a match network to tune to one pulse state (e.g., first power level 201 or high power state) and using generator frequency tuning to try to match the remaining pulse state(s) (e.g., second power level 202 or low power state). This can result in reflected power during the remaining pulse states because frequency tuning may not be able to fully compensate for the impedance changes. Reflected power can have negative effects on the efficiency and stability of the plasma process and is often unacceptable for plasma processing applications such as semiconductor manufacturing. Moreover, conventional approaches to matching load fluctuations may involve continuous tuning of a variable capacitor, causing wear to the leadscrew of the variable capacitor and reducing lifetime.

Returning to FIG. 1, to address the above-described issues, the match network 104 is enhanced to perform impedance matching for two or more impedance states. In particular, in addition to a variable capacitance 131 configured to tune to a first impedance state, the variable reactance section 120 includes at least one array of one or more solid-state capacitances 132 configured to tune to a second impedance state. The array of one or more solid-state capacitances 132 are configured to be dynamically placed in parallel (e.g., via one or more solid-state switches) with the variable capacitance 131. In other words, each solid-state capacitance may be switchably in parallel with the variable capacitance 131. Advantageously, this arrangement of the variable reactance section 120 enables the match network 104 to quickly and accurately match multiple impedance states, and reduces reliance on continuous variable capacitor adjustment, thus preventing wear and extending the operating life of its variable capacitance. Additionally, as compared to using entirely solid-state capacitors and switches, this configuration that combines the use of variable capacitance and solid-state capacitance reduces the number of solid-state switches, thus reducing power dissipation due to switching and improving cooling of individual switches.

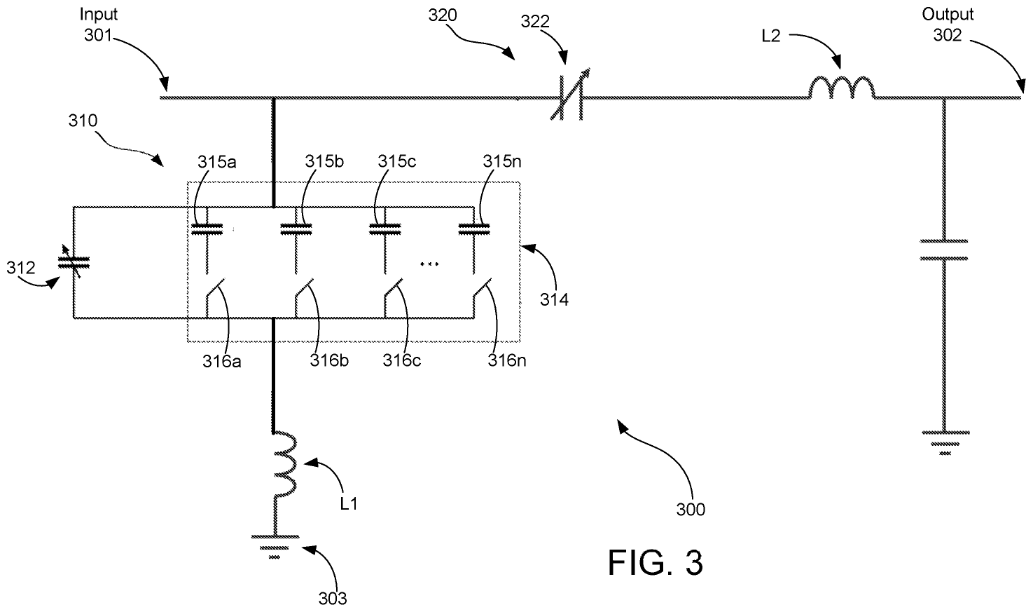

FIG. 3 shows a variable reactance section 300 that is an example of the variable reactance section 120 of FIG. 1. In the variable reactance section 300, a first variable capacitance 312 and an array 314 of one or more solid-state capacitances 315 are examples of the variable capacitance 131 and array of one or more solid-state capacitances 132, respectively. The variable reactance section 300 is an example of an “L” match network topology including a shunt leg 310 and series leg 320, although it will be appreciated that the concepts discussed herein are also applicable to other arrangements including “T” and “Pi” architectures. The shunt leg 310 includes one or more elements disposed between input 301 and ground 303, and the series leg 320 includes one or more elements disposed between input 301 and output 302.

Generally speaking, the element controller 122 is configured to control various components of the variable reactance section 300 to transform the impedance seen at the input 301 (connected to a source or generator 102) to match the load impedance at the output 302. For example, in the topology shown in FIG. 3, adjusting the capacitance of the shunt leg 310 may primarily affect the real part of the impedance presented to the generator 102, and adjusting the capacitance of the series leg 320 may primarily affect the imaginary part of the impedance presented to the generator 102. The element controller 122 may therefore adjust the capacitance of the shunt leg 310 and the series leg 320 to offset real and imaginary impedance changes of the plasma load, shifting the impedance closer to the desired match.

In this example, the shunt leg 310 includes the first variable capacitance 312 and the array 314 in parallel with one another. The array 314 includes one or more solid-state capacitances 315a-n and corresponding one or more switches 316a-n. Accordingly, solid-state capacitances 315a-n are switchably in parallel with the first variable capacitance 312 as part of the shunt leg 310. Additionally, in this example, the series leg 320 includes a second variable capacitance 322. In one embodiment, the element controller 122 controls the variable capacitances 312/322 as the primary adjustable elements to tune to a first impedance state, and controls the array 314 of solid-state capacitances 315a-n to tune to one or more second impedance states. That is, the element controller 122 is configured to control the switches 316 to add or remove the solid-state capacitances 315 into or out of the circuit, therefore tuning to additional pulse states and/or impedance excursions.

In one embodiment, the match network 104 uses the array 314 to tune to multiple pulses or power states. For instance, for the first power level 201 (e.g., high power state), the element controller 122 may adjust the capacitive values of the first variable capacitance 312 and/or second variable capacitance 322 while the array 314 of one or more solid-state capacitances 315 is in a first switched configuration (e.g., some combination of solid-state capacitance 315 switched in or out). To tune to the second power level 202 (e.g., low power state), the element controller 122 operates one or more switches 316 to change from the first switched configuration to a second switched configuration, thus adding or removing capacitance and adjusting impedance to the changed impedance state due to the change in power level. Advantageously, the element controller 122 may control the array 314 to quickly switch between two or more impedance states, and match the source and load impedances for two or more types of power pulses applied to the plasma.

Alternatively or additionally, the match network 104 may use the array 314 to quickly and continuously tune the match to small variations in plasma load impedance. For instance, the element controller 122 may tune the first variable capacitance 312 to a first impedance state that is based on an average impedance value of a plasma load. Then the element controller 122 may continuously control the switches 316 of the array 314 to add or remove the calculated/desired solid-state capacitance 315 for impedance matching to one or more second impedance states based on impedance fluctuation of the plasma load from the average impedance value. Advantageously, the element controller 122 may control the array 314 to quickly switch in more or less solid-state capacitance 315, maintaining the match between the source and load impedances in real-time despite load impedance fluctuations and without continuous adjustment of a variable capacitor.

In some embodiments, the match network 104 and/or variable reactance section 120/300 may function in connection with the frequency-tuning subsystem 103 to transform an impedance at the output (e.g., output 114 of FIG. 1 or output 302 of FIG. 3) to a desired impedance value for the load, ZL (that is presented to the transmission line 108 at an input 112 or input 301 of the match network 104). For instance, as previously mentioned, capacitance adjustment of the shunt leg 310 may primarily affect the real part of the impedance presented to the generator 102, and capacitance adjustment of the series leg 320 may primarily affect the imaginary part of the impedance presented to the generator 102. Here, to complete the process of impedance matching to a second impedance state or pulse, the frequency-tuning subsystem 103 may adjust the frequency of the generator 102 (i.e., perform frequency tuning) such that the imaginary part of the impedance is tuned along with the real part adjusted by the control of the array 314.

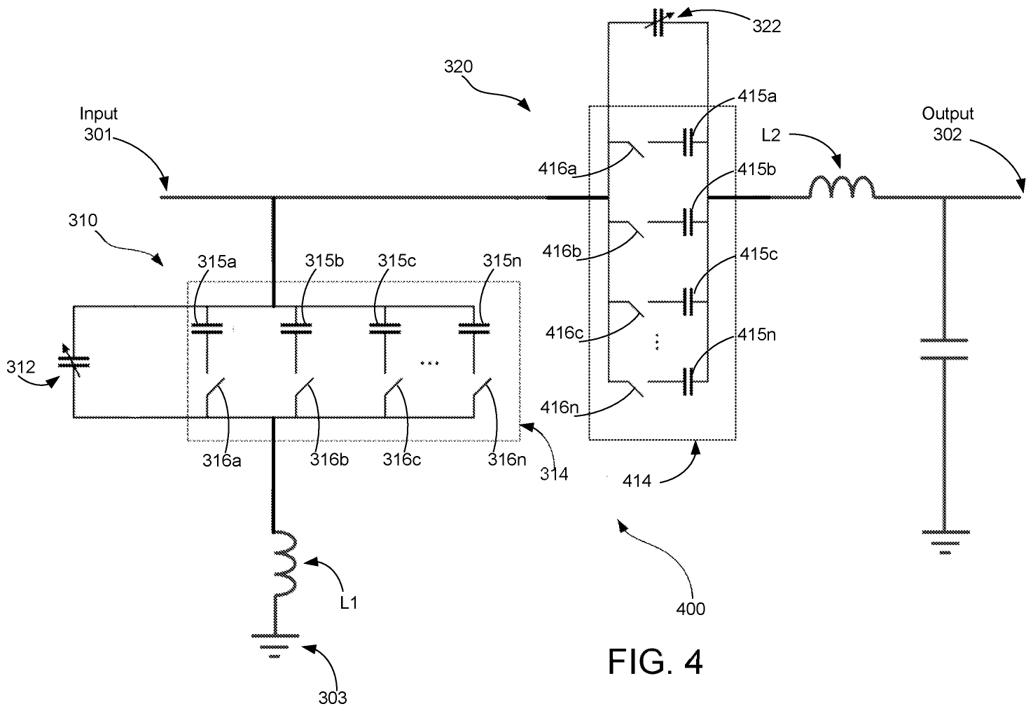

FIG. 4 shows a variable reactance section 400 that is another example of the variable reactance section 120 of FIG. 1. The variable reactance section 400 has a similar configuration as the variable reactance section 300 described above. Here, however, the variable reactance section 400 includes two arrays of solid-state capacitances, one for each leg 310/320, to enable impedance matching without the use of frequency tuning.

In particular, the series leg 320 includes an additional array 414 that is in parallel with the second variable capacitance 322. The additional array 414 includes one or more additional solid-state capacitances 415a-n and corresponding one or more additional switches 416a-n. The additional solid-state capacitances 415a-n are switchably in parallel with the second variable capacitance 322 as part of the series leg 320. Accordingly, much of the description above of the array 314 may also apply to the additional array 414, except that the additional array 414 may be used to control the capacitance of the series leg 320, whereas the array 314 may be used to control the capacitance of the shunt leg 310.

For example, in a multi-pulsing embodiment, the element controller 122 may adjust the variable capacitances 312/322 for impedance matching for a first power pulse, and control arrays 314/414 for impedance matching for a second power pulse. Control of the additional array 414 may primarily affect the imaginary part of the impedance. Accordingly, the variable reactance section 400 is configured to tune to multiple pulses without frequency tuning. Alternatively or additionally, the element controller 122 may operate the additional array 414 to adjust the capacitance of the series leg 320 to tune to plasma load fluctuations without frequency tuning.

Although FIGS. 3-4 are discussed with respect to a dual-pulsing example, it will be appreciated that the concepts are also applicable to embodiments with three or more multi-pulse states. That is, for each additional pulse state, one or two additional arrays of solid-state capacitances and associated switch(es) may be added. Alternatively or additionally, an increased number of solid-state capacitances may be added to an array and/or assigned to match additional impedance states. For example, for a third pulse state, the variable reactance section 400 may include an increased number of solid-state capacitances 315 configured to be placed in parallel as part of the shunt leg 310. The imaginary portion of impedance for the third pulse may be completed with frequency tuning. Alternatively, an increased number of solid-state capacitances 415 may be placed in parallel as part of the series leg 320 for impedance matching for the third pulse without frequency tuning. The number of solid-state capacitances available in an array may be based on the solid-state capacitance values, desired capacitance range/granularity, match topology, number of impedance states to match, etc.

Additionally, as previously mentioned, alternative arrangements of the variable capacitances are contemplated. For example, a T-network match arrangement and Pi-network match arrangement may be configured to adjust impedance via elements corresponding with the shunt elements and series of elements described in FIGS. 3-4. In some arrangements, one element may be referred to as a load element (e.g., primarily tunes the real portion of impedance), and another element may be referred to as a tune element (e.g., primarily tunes the imaginary portion of impedance).

In one embodiment, variable capacitances 312/322 each comprise one or more variable capacitors such as variable vacuum capacitors and/or variable air capacitors. Variable capacitors may include moving parts, such as rotors and/or stators, that can be electronically or manually controlled to adjust capacitance. By contrast, solid-state capacitances 315/415 may each comprise one or more fixed capacitors having a fixed and unchangeable capacitance value (e.g., having dielectric materials and metal plates and excluding adjustable or mechanical parts). The switches 316/416 may each comprise a solid-state switch such as Field-Effect Transistor (FET), Insulated Gate Bipolar Transistor (IGBT), etc. In some embodiments, arrays 314/414 include a plurality of solid-state capacitances 315/415 and corresponding switches 316/416 such as such as two, four, eight, or sixteen solid-state capacitances configured for switchable parallel placement. Additional elements of the variable reactance sections 300/400 are possible, such as inductive elements L1 and L2 as part of the shunt leg 310 and series leg 320, respectively.

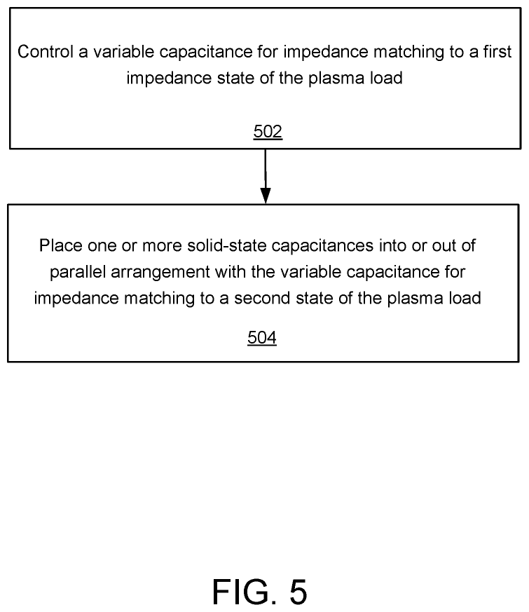

FIG. 5 is a flowchart illustrating a method of impedance tuning in an example embodiment. The steps of the method are described with reference to the plasma processing system 100 of FIG. 1 and variable reactance section 300 of FIG. 3, but those skilled in the art will appreciate that the method may be performed in other systems, variable reactance configurations, and match topologies. The steps of the flowcharts described herein are not all inclusive, may include other steps not shown, and may be performed in an alternative order.

In step 502, a controller controls the variable capacitance 131/312 for impedance matching to a first impedance state of a plasma load. In step 504, the controller switches one or more solid-state capacitances 132/315 into or out of parallel arrangement with the variable capacitance 131/312 for impedance matching to a second impedance state of the plasma load. In some embodiments, the first and second impedance states correspond with plasma impedances due to first and second power pulses applied to the plasma. Alternatively or additionally, the first and second impedance states may correspond with an average impedance of the plasma and an impedance fluctuation from the average.

### EXAMPLE

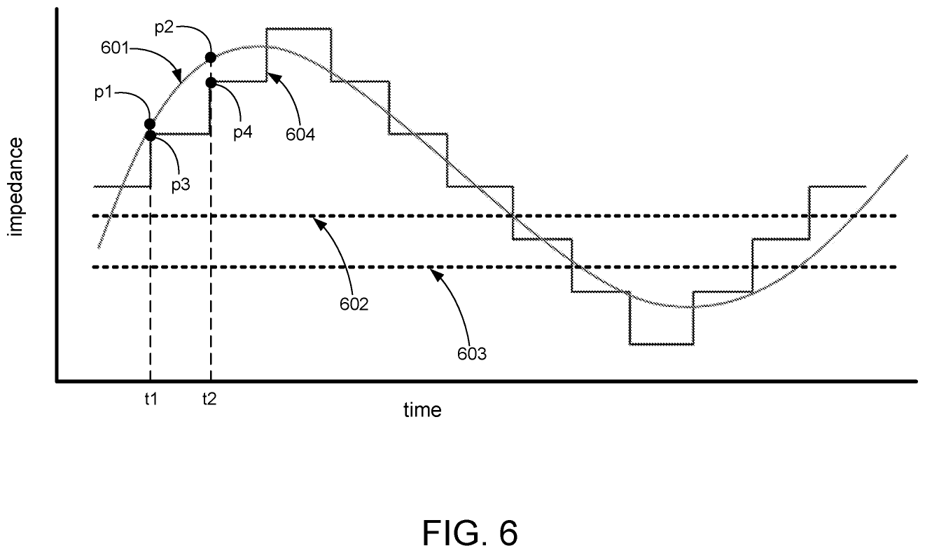

FIG. 6 is a graph depicting an example of using a variable capacitance and solid-state capacitance in combination for impedance matching to load fluctuation. For purposes of discussion, this example is discussed with respect to the variable reactance section 300 of FIG. 3 and plasma processing system 100 of FIG. 1, though it will be appreciated that the principles may apply to alternative variable reactance configurations, plasma processing systems, match topologies, etc.

Suppose, for this example, measurement section 124 monitors a plasma load impedance 601 which fluctuates over time. For instance, in a time increment from time t1 to time t2, the plasma load impedance 601 increases from a first value p1 to a second value p2. Moreover, over a longer period of time, the plasma load impedance 601 is determined to have an average impedance value 602. After determining or obtaining the average impedance value 602, the element controller 122 tunes the variable capacitance 312 to a capacitance value that is determined or calculated to impedance match based on the average impedance value 602. In this example, the average impedance value 602 is a constant value for a period of time, and therefore after the variable capacitance 312 is set it may remain unadjusted for the period of time.

The element controller 122 may use the average impedance value 602 as a basis or point of reference for adding or removing solid-state capacitance 315 in increments of time to maintain impedance matching despite load fluctuations. In other words, the element controller 122 may determine one or more solid-state capacitances 315 to switch in or out of the circuit such that its capacitance, in combination with the set capacitance of the variable capacitance 312, provides an impedance match to an approximated load impedance 604. The approximated load impedance 604 adjusts or steps in increments of time to approximate the fluctuation of the plasma load impedance 601. The approximation or accuracy thereof, may be based, at least in part, on the desired granularity/range of solid-state capacitor values and/or the desired switching frequency of the array 314.

For example, for the time increment from time t1 to time t2, the measurement section 124 detects a change of the plasma load impedance 601 from the first value p1 to the second value p2. In response to the detected change, and/or determining the detected change exceeds a threshold for the increment or window of time, the element controller 122 may add or remove the appropriate solid-state capacitances 315 to adjust impedance from a third value p3 that most closely approximates the first value p1, and to a fourth value p4 that most closely approximates the second value p2. The element controller 122 may therefore determine one or more solid-state capacitances 315 to switch based on the detected impedance fluctuation value, and a determination of capacitance value to match, or most closely approximate the match, to the impedance fluctuation value. For embodiments in which the solid-state capacitances 315 have different capacitor values than each other, the element controller 122 may determine which one(s) of the solid-state capacitances 315 to switch based on a mapping of capacitance values to switches 316.

Alternatively or additionally, the element controller 122 may determine to, or otherwise be instructed to, tune the variable capacitance 312 to a capacitance value to match an offset impedance value 603 that is based on the average impedance value 602. For instance, since the plasma load impedance 601 may deviate in two directions (i.e., above and below the average impedance value 602), it may be desirable for some combination of solid-state capacitances 315 to be switched in with the variable capacitance 312 for setting to the average impedance value 602. In that way, the solid-state capacitances 315 can be added or removed to impart impedance change in both directions.

Accordingly, the element controller 122 may set variable capacitance 312 for impedance matching to the offset impedance value 603, and set the solid-state capacitance 315 to a first switched configuration for, in conjunction with the variable capacitance 312, impedance matching to the average impedance value 602. Thereafter, the element controller 122 may change the solid-state capacitance 315 to a second switched configuration (e.g., add or remove capacitance relative to the first switched configuration) for impedance matching to the approximated load impedance 604. In some embodiments, after obtaining the average impedance value 602, the element controller 122 may determine the offset impedance value 603 based on a maximum available capacitance value of the array 314 and/or a desired range/direction of impedance change from the average.

Although not shown to keep the depiction of FIG. 1 simple and clear, one of ordinary skill in the art will readily appreciate that the generator 102, the match network 104, and/or the external controller 107 may include a user interface to enable an operator of the plasma processing system 100 to control and monitor the plasma processing system 100. It should also be noted that the depiction of the external controller 107 should not be construed to mean that common supervisory control over the generator 102 and match network 104 is required.

The plasma 109 may be a plasma formed in the plasma chamber 105, which is known for performing processing such as the etching of substrates or the deposition of thin layers upon substrates. The plasma 109 is typically achieved by the formation of plasmas within low pressure gases. The plasma is initiated and sustained by the generator 102 (and potentially additional generators). The generator 102 may apply power to the plasma chamber 105 by a conventional 13.56 MHz signal, but other frequencies may also be utilized.

The external controller 107 may be realized by hardware or hardware in connection with software, and the external controller 107 may be coupled to several components of a plasma processing system 100 including the generator 102, match network 104, equipment coupled to the plasma chamber 105, other generators, mass flow controllers, etc. The input sensor 116 may be realized by a conventional dual directional coupler (known to those of ordinary skill in the art) that includes sensing circuitry that provides outputs indicative of forward and reflected power at the input of the match network 104. The input sensor 116 may also be realized by a conventional voltage-current (V/I) sensor (known to those of ordinary skill in the art) that includes sensing circuitry that provides outputs indicative of voltage, current, and a phase between the voltage and current. As a nonlimiting example, a directional coupler may be used to realize the input sensor 116. The input sensor 116 may also comprise a frequency sensor known to those of ordinary skill in the art. Moreover, the input sensor 116 may be realized by more than one separate sensors (e.g., a separate voltage sensor and a separate current transducer). In other words, although a single block is depicted for each of the input sensor 116, the block may represent one or more sensors (and potentially processing circuitry).

The measurement section 124 may include processing components to sample, filter, and digitize the outputs of the input sensor 116 for utilization by the element controller 122. Because an impedance of the load, ZL tends to vary during processing of a workpiece (e.g., a substrate), the element controller 122 may operate on an ongoing basis to adjust the variable reactance section 120 to change its impedance to compensate for fluctuations in the impedance of the dynamic load. For instance, the measurement section 124 and/or element controller 122 may monitor an impedance state of a plasma load, and the element controller 122 may control the variable capacitance 131 to impedance match to a first impedance state of the plasma load, and in response to detecting an impedance change of the plasma load to a second impedance state, switch one or more solid-state capacitances 132 into or out of parallel arrangement with the variable capacitance 131 to impedance match to the second state of the plasma load.

In some variations, a communication link 126 communicatively couples the generator 102 and the match network 104 to enable informational and/or control signals to be sent between the generator 102 and the match network 104. For instance, the generator 102 and/or internal controller 119 may provide instructions for controlling the variable capacitance 131 and/or solid-state capacitances 132 to predetermined capacitance values which provide a match for, and synchronize with, power pulses provided by the generator 102. But many implementations do not require the communication link 126, and it should be recognized that in these implementations the match network 104 may operate substantially independent of the generator 102. The specific embodiment of the match network 104 in FIG. 1 (in which the element controller 122 and the measurement section 124 are within the internal controller 119 of the match network 104) may be beneficial for one or more reasons. For example, the internal controller 119 of the match network 104 may have access to internal parameters of the match network 104 that the external controller 107 (or other external controllers) does not have access to. As another example, the internal controller 119 is in closer proximity to the input sensor 116; thus, data from the sensor 116 may be received and processed relatively quickly. In addition, the components of the internal controller 119 may be realized on the same printed circuit board or even the same chip (as a system on a chip); thus, very fast bus communications (without the need to translate to another communication protocol, such as a local area network protocol) may be carried out between the components of some embodiments of the internal controller 119.

But in variations of the embodiment depicted in FIG. 1, it may be beneficial to distribute one or more of the components of the match network 104 and/or generator 102, so other configurations are certainly contemplated. For example, the input sensor 116 may be located outside of the match network 104. As another example, the input sensor 116 may reside within the generator 102 and the generator 102 may provide a signal indicative of electrical parameters at the output of the generator 102 to the measurement section 124. Moreover, one or more of the components of the internal controller 119 (e.g., one or more of the element controller 122 and measurement section 124 may be located apart from the match network 104). For example, it is contemplated that one or more components of the internal controller 119 may be located remotely from the match network 104 and may be coupled to the match network 104, the generator 102, or the external controller 107 by a network connection. It is also contemplated that the frequency-tuning subsystem 103 may be realized, at least in part in the external controller 107. In many instances, operators of plasma processing systems (such as the system depicted in FIG. 1) may prefer to utilize a centralized controller (such as the external controller 107) for convenience, and because the operators may prefer to have control over the logic and algorithms that are utilized in the generator 102 and/or match network 104.

By way of further example, it should also be recognized that the components of the match network 104 are depicted as logical components and that the depicted components may be realized by common constructs (e.g., a common central processing unit and non-volatile memory) that are closely integrated, or the depicted components may be further distributed. For example, the functionality of the measurement section 124 may be distributed with the input sensor 116 so that signals output from the input sensor 116 are digital signals that have been processed and digitalized, which enables the element controller 122 to directly receive processed signals from the input sensor 116. The specific examples of the distribution of the depicted functions are not intended to be limiting because it is certainly contemplated that various alternatives may be utilized depending upon the type of hardware that is selected and the extent to which software (e.g., embedded software) is utilized.

The element controller 122 may be configured to obtain an input impedance at the input of the match network 104. The input impedance is also referred to herein as a value of the impedance of the load, ZL, presented to the generator 102. As those of ordinary skill in the art will appreciate, the input sensor 116 may provide the necessary measurements of power-related parameters such as voltage, current, phase between the voltage and current, forward power, and reflected power, which may be used to calculate input impedance.

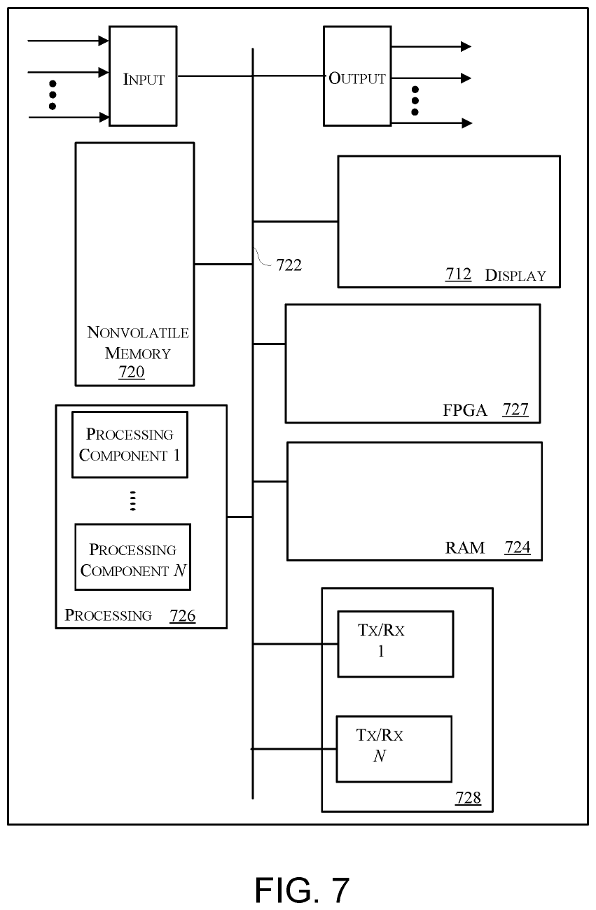

The methods described in connection with the embodiments disclosed herein may be embodied directly in hardware, in processor executable instructions encoded in non-transitory machine readable medium, or as a combination of the two. Referring to FIG. 7 for example, shown is a block diagram depicting physical components that may be utilized to realize one or more of the frequency-tuning subsystem 103, external controller 107, and/or internal controller 119. As shown, in this embodiment a display portion 712 and nonvolatile memory 720 are coupled to a bus 722 that is also coupled to random access memory (“RAM”) 724, a processing portion (which includes N processing components) 726, a field programmable gate array (FPGA) 727, and a transceiver component 728 that includes N transceivers. Although the components depicted in FIG. 7 represent physical components, FIG. 7 is not intended to be a detailed hardware diagram; thus, many of the components depicted in FIG. 7 may be realized by common constructs or distributed among additional physical components. Moreover, it is contemplated that other existing and yet-to-be developed physical components and architectures may be utilized to implement the functional components described with reference to FIG. 7.

Display portion 712 generally operates to provide a user interface for a user, and in several implementations, the display is realized by a touchscreen display. For example, display portion 712 can be used to control and interact with internal controller 119 in connection with characterizing a dynamic load to produce an associated impedance trajectory. The user interface may also be used to enable an operator to select particular power levels, frequencies, and pulse parameters for the generator 102. In general, the nonvolatile memory 720 is non-transitory memory that functions to store (e.g., persistently store) data and machine readable (e.g., processor readable and executable) code (including executable code that is associated with effectuating the methods described herein). In some embodiments, for example, the nonvolatile memory 720 includes bootloader code, operating system code, file system code, and non-transitory processor-executable code to facilitate the execution of the methods (e.g., the method described with reference to FIG. 5) described herein.

In many implementations, the nonvolatile memory 720 is realized by flash memory (e.g., NAND or ONENAND memory), but it is contemplated that other memory types may be utilized as well. Although it may be possible to execute the code from the nonvolatile memory 720, the executable code in the nonvolatile memory is typically loaded into RAM 724 and executed by one or more of the N processing components in the processing portion 726.

In operation, the N processing components in connection with RAM 724 may generally operate to execute the instructions stored in nonvolatile memory 720 to realize the functionality of frequency-tuning subsystem 103 and element controller 122. For example, non-transitory processor-executable instructions to effectuate the methods described herein may be persistently stored in nonvolatile memory 720 and executed by the N processing components in connection with RAM 724. As one of ordinary skill in the art will appreciate, the processing portion 726 may include a video processor, digital signal processor (DSP), graphics processing unit (GPU), and other processing components.

In addition, or in the alternative, the field programmable gate array (FPGA) 727 may be configured to effectuate one or more aspects of the methodologies described herein. For example, non-transitory FPGA-configuration-instructions may be persistently stored in nonvolatile memory 720 and accessed by the FPGA 727 (e.g., during boot up) to configure the FPGA 727 to effectuate the functions of frequency-tuning subsystem 103 and element controller 122.

The input component may operate to receive signals (e.g., from sensor 116) that are indicative of one or more properties of the power that is output by the generator 102 and that characterize the dynamic load, Zp. The signals received at the input component may include, for example, voltage, current, forward power, reflected power, and dynamic load impedance. The output component generally operates to provide one or more analog or digital signals to effectuate an operational aspect of the match network 104 and/or generator 102. For example, the output portion may transmit the adjusted frequency to an exciter of the generator 102 during frequency tuning. The output may also be used to control elements described herein including positions of the variable capacitance 131, switches of the array of one or more solid-state capacitances 132, etc.

The depicted transceiver component 728 includes N transceiver chains, which may be used for communicating with external devices via wireless or wireline networks. Each of the N transceiver chains may represent a transceiver associated with a particular communication scheme (e.g., WiFi, Ethernet, Profibus, etc.).

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

What is claimed is:

1. A match network comprising:
a variable capacitance;
one or more solid-state capacitances switchably in parallel with the variable capacitance; and
a controller configured to:
control the variable capacitance to impedance match to a first impedance state of a plasma load; and
switch at least one solid-state capacitance into or out of parallel arrangement with the variable capacitance to impedance match to a second state of the plasma load.

2. The match network of claim 1, wherein the controller is configured to:
tune the variable capacitance to impedance match to the first impedance state based on a first power pulse applied to the plasma load; and
switch the at least one solid-state capacitance to impedance match to the second impedance state based on a second power pulse applied to the plasma load that is different than the first power pulse.

3. The match network of claim 2, wherein the controller is configured to:
determine a first switched configuration of the one or more solid-state capacitances to impedance match for the first power pulse;
determine a second switched configuration of the one or more solid-state capacitances to impedance match for the second power pulse; and
toggle between the first switched configuration and the second switched configuration for the first power pulse and the second power pulse, respectively.

4. The match network of claim 1, wherein the controller is configured to:
tune the variable capacitance to impedance match to the first impedance state based on an average impedance value of a plasma load over a period of time;
detect an impedance fluctuation of the plasma load from the average impedance value; and
switch the at least one solid-state capacitance to impedance match to one or more second impedance states based on the detected impedance fluctuation of the plasma load.

5. The match network of claim 4, wherein the controller is configured to:
tune the variable capacitance based on an impedance value that is offset from the average impedance value;
switch the one or more solid-state capacitances to a first switched configuration to impedance match to the average impedance value in conjunction with the variable capacitance; and
switch the one or more solid-state capacitances to a second switched configuration to impedance match based on the detected impedance fluctuation of the plasma load.

6. The match network of claim 1, wherein the controller is configured to:
monitor an impedance state of the plasma load; and
in response to detecting an impedance change of the plasma load from the first impedance state to the second impedance state, switch the at least one solid-state capacitance into or out of parallel arrangement with the variable capacitance to impedance match to the second state of the plasma load.

7. The match network of claim 1, further comprising:
a first array including a first plurality of solid-state capacitances and a first plurality of switches corresponding with the first plurality of solid-state capacitances, wherein the first array is in parallel with the variable capacitance and is part of a shunt leg; and
a second array including a second plurality of solid-state capacitances and a second plurality of switches corresponding with the second plurality of solid-state capacitances, wherein the second array is in parallel with a second variable capacitance and is part of a series leg;
wherein the controller is configured to operate the first plurality of switches and the second plurality of switches to impedance match to the second state.

8. A method comprising:
controlling a variable capacitance for impedance matching to a first impedance state of a plasma load; and
switching one or more solid-state capacitances into or out of parallel arrangement with the variable capacitance for impedance matching to a second impedance state of the plasma load.

9. The method of claim 8, further comprising:
providing power to the plasma load, the power including a first power pulse and a second power pulse that is different than the first power pulse;
tuning the variable capacitance for impedance matching to the first impedance state based on the first power pulse applied to the plasma load; and
switching the one or more solid-state capacitances for impedance matching to the second impedance state based on the second power pulse applied to the plasma load.

10. The method of claim 9, further comprising:
determining a first switched configuration of the one or more solid-state capacitances to impedance match for the first power pulse;
determining a second switched configuration of the one or more solid-state capacitances to impedance match for the second power pulse; and
toggling between the first switched configuration and the second switched configuration for the first power pulse and the second power pulse, respectively.

11. The method of claim 8, further comprising:
tuning the variable capacitance for impedance matching to the first impedance state based on an average impedance value of the plasma load over a period of time;
detecting an impedance fluctuation of the plasma load from the average impedance value; and
switching at least one solid-state capacitance for impedance matching to the second impedance state based on the detected impedance fluctuation of the plasma load from the average impedance value.

12. The method of claim 11, further comprising:
tuning the variable capacitance based on an impedance value that is offset from the average impedance value;
switching the one or more solid-state capacitances to a first switched configuration to impedance match to the average impedance value in conjunction with the variable capacitance; and
switching the one or more solid-state capacitances to a second switched configuration to impedance match based on the detected impedance fluctuation of the plasma load.

13. The method of claim 8, wherein:
the variable capacitance is a variable vacuum capacitance.

14. A non-transitory processor-readable medium comprising instructions for execution by a processor or for configuring a field programmable gate array, the instructions comprising instructions to:
control a variable capacitance for impedance matching to a first impedance state of a plasma load; and
switch one or more solid-state capacitances into or out of parallel arrangement with the variable capacitance for impedance matching to a second impedance state of the plasma load.

15. The non-transitory processor-readable medium of claim 14, wherein the instructions comprise instructions to:
tune the variable capacitance for impedance matching to the first impedance state based on a first power pulse applied to the plasma load; and
switch the one or more solid-state capacitances for impedance matching to the second impedance state based on a second power pulse applied to the plasma load that is different than the first power pulse.

16. The non-transitory processor-readable medium of claim 15, wherein the instructions comprise instructions to:
determine a first switched configuration of the one or more solid-state capacitances to impedance match for the first power pulse;
determine a second switched configuration of the one or more solid-state capacitances to impedance match for the second power pulse; and
toggle between the first switched configuration and the second switched configuration for the first power pulse and the second power pulse, respectively.

17. The non-transitory processor-readable medium of claim 14, wherein the instructions comprise instructions to:
tune the variable capacitance for impedance matching to the first impedance state based on an average impedance value of the plasma load over a period of time;
detect an impedance fluctuation of the plasma load from the average impedance value; and
switch at least one solid-state capacitance for impedance matching to the second impedance state based on the detected impedance fluctuation of the plasma load from the average impedance value.

18. The non-transitory processor-readable medium of claim 17, the instructions comprise instructions to:
tune the variable capacitance based on an impedance value that is offset from the average impedance value;
switch the one or more solid-state capacitances to a first switched configuration to impedance match to the average impedance value in conjunction with the variable capacitance; and
switch the one or more solid-state capacitances to a second switched configuration to impedance match based on the detected impedance fluctuation of the plasma load.

19. The non-transitory processor-readable medium of claim 14, wherein:
the variable capacitance is a variable vacuum capacitance.

20. The non-transitory processor-readable medium of claim 14, wherein the instructions comprise instructions to:
control a first array including a first plurality of solid-state capacitances and a first plurality of switches corresponding with the first plurality of solid-state capacitances, wherein the first array is in parallel with the variable capacitance and is part of a shunt leg of a match network; and
control a second array including a second plurality of solid-state capacitances and a second plurality of switches corresponding with the second plurality of solid-state capacitances, wherein the second array is in parallel with a second variable capacitance and is part of a series leg of the match network;
wherein the control of the first array and the second array includes operating the first plurality of switches and the second plurality of switches to impedance match to the second state.
